(19) United States
(12) Patent Application Publication
(10) Pub. No.: US 2012/0091994 A1
(43) Pub. Date: Apr. 19, 2012

(54) INTEGRATED APPARATUS FOR SENSING CURRENT

(75) Inventors: Dong Ok HAN, Suwon (KR); Kyung Uk KIM, Seoul (KR)

(73) Assignee: SAMSUNG ELECTRO-MECHANICS CO., LTD., Suwon (KR)

(21) Appl. No.: 13/029,179

(22) Filed: Feb. 17, 2011

(30) Foreign Application Priority Data
Oct. 18, 2010 (KR) 10-2010-0101547

(51) Int. Cl. G01R 33/07

(52) U.S. Cl. 324/117 H

(57) ABSTRACT

There is provided an integrated apparatus for sensing current including: a voltage regulator; a Hall effect device receiving current by the voltage regulator and outputting hall voltage in proportional to strength of a magnetic field; and a coil having one end connected to a first connecting terminal and the other end connected to a second connecting terminal, wound to have a plurality of turns along a circumference of the Hall effect device on the same plane spaced apart by a predetermined distance from the Hall effect device in a direction of the magnetic field, and forming the magnetic field according to current flowing through the first connecting terminal and the second connecting terminal, wherein the Hall effect device and the coil are integrated within one chip. A manufacturing cost of a product may be reduced, simultaneously with sensing the current without loss of the magnetic field according to a distance through the above-mentioned configuration.

### CROSS-REFERENCE TO RELATED APPLICATIONS

This application claims the priority of Korean Patent Application No. 10-2010-0101547 filed on Oct. 18, 2010, in the Korean Intellectual Property Office, the disclosure of which is incorporated herein by reference.

### BACKGROUND OF THE INVENTION

1. Field of the Invention

The present invention relates to an apparatus for sensing current, and more particularly, to an integrated apparatus for sensing current capable of reducing a manufacturing cost of a product, simultaneously with sensing current without loss of a magnetic field according to distance by integrating a Hall effect device outputting hall voltage in proportion to a strength of the magnetic field and a coil generating the magnetic field within one chip.

2. Description of the Related Art

Generally, as methods of sensing current flowing in a wire, there are a shunt resistor method sensing current flowing to a wire in voltage form using a shunt resistor, a current transformer (CT) method using a ring-shaped core, a hall integrated circuit (IC) method, and the like. These varied methods have been appropriately used according to cost and a use thereof.

Among them, the hall IC method uses a Hall effect, which indicates that when the magnetic field is applied to any conductor through which current flows, Lorentz's force is generated in a direction perpendicular to the directions of both the current and the magnetic field, such that voltage (hall voltage) is generated across the conductor.

Since the hall IC method is operated by sensing the magnetic field generated in the wire, it has a difficulty in sensing a magnetic field, as a magnitude of the current flowing to the wire becomes small or a distance between the wire and the hall IC is increased.

### SUMMARY OF THE INVENTION

An aspect of the present invention provides an integrated apparatus for sensing current capable of reducing a manufacturing cost of a product, simultaneously with sensing current without loss of a magnetic field according to a distance.

According to an aspect of the present invention, there is provided a integrated apparatus for sensing current including: a voltage regulator; a Hall effect device receiving current by the voltage regulator and outputting hall voltage in proportion to strength of a magnetic field; and a coil having one end connected to a first connecting terminal and the other end connected to a second connecting terminal, wound to have a plurality of turns along a circumference of the Hall effect device on the same plane therewith spaced apart by a predetermined distance from the Hall effect device in a direction of the magnetic field, and forming the magnetic field according to current flowing through the first connecting terminal and the second connecting terminal, wherein the Hall effect device and the coil are integrated within one chip.

The coil may be disposed over or under the Hall effect device.

The integrated apparatus for sensing current may further include resistor for limiting current between the first connecting terminal and a current input terminal or between the second connecting terminal and a current output terminal.

The integrated apparatus for sensing current may further include a transformer having a primary side connected to a current input terminal and a current output terminal and a secondary side connected to the first connecting terminal and the second connecting terminal.

The integrated apparatus for sensing current may further include an amplifier amplifying the hall voltage outputted from the Hall effect device.

The integrated apparatus for sensing current may further include a Schmidt trigger or an analog-to-digital converter converting the amplified voltage into a digital signal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view showing an integrated apparatus for sensing current according to an exemplary embodiment of the present invention;

FIGS. 2A and 2B are views showing positions of a Hall effect device and a coil according to an exemplary embodiment of the present invention;

FIG. 3 is a view showing an integrated apparatus for sensing current according to an exemplary embodiment of the present invention; and

FIG. 4 is a view showing an integrated apparatus for sensing current according to another exemplary embodiment of the present invention.

### DETAILED DESCRIPTION OF THE PREFERRED EMBODIMENT

Hereinafter, exemplary embodiments of the present invention will be described in detail with reference to the accompanying drawings, which will fully convey the concept of the invention to those skilled in the art. Moreover, detailed descriptions related to well-known functions or configurations will be ruled out in order not to unnecessarily obscure the subject matter of the present invention.

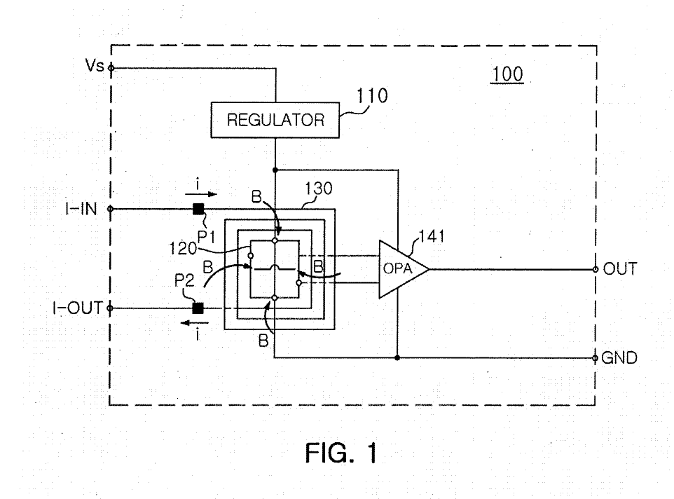

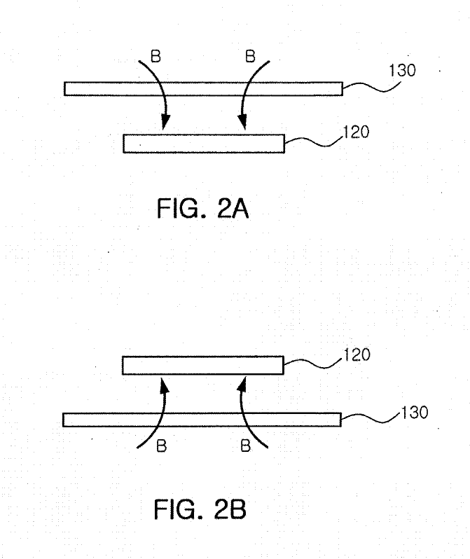

FIG. 1 is a view showing an integrated apparatus 100 for sensing current according to an exemplary embodiment of the present invention. The integrated apparatus 100 for sensing current may be configured to include a voltage regulator 110, a Hall effect device 120, and a coil 130 that is installed to be spaced apart by a predetermined interval from the Hall effect device 120, and an amplifier 141. Meanwhile, FIGS. 2A and 2B are views showing positions of a Hall effect device and a coil according to an exemplary embodiment of the present invention.

Referring to FIG. 1, the voltage regulator 110 receives voltage from an external terminal Vs to generate a predetermined voltage without ripple. The generated voltage is supplied to the Hall effect device 120 and the amplifier 141.

The Hall effect device 120 is one of various magnetic field sensors. More specifically, current flows into the Hall effect device 120 by the voltage from the voltage regulator 110, and hall voltage in proportion to the magnitude of a magnetic field B generated by current flowing to the coil 130 is generated. The generated hall voltage is transferred to the amplifier 141.

The coil 130 has one end connected to a first connecting terminal P1 and the other end connected to a second connecting terminal P2, is wound to have a plurality of turns along a circumference of the Hall effect device 120 on the same plane spaced apart by a predetermined distance from the Hall effect device 120 in a direction of the magnetic field, and forms the magnetic field B according to current i flowing through the first connecting terminal P1 and the second connecting terminal P2. Meanwhile, the first connecting terminal P1 and a current input terminal I-IN may be interconnected using a bonding wire, and the second connecting terminal P2 and a current output terminal I-OUT may also be interconnected using a bonding wire. A position relation between the coil 130 and the Hall effect device 120 is shown in FIGS. 2A and 2B.

Referring to FIGS. 2A and 2B, the coil 130 may be disposed over the Hall effect device 120, as shown in FIG. 2A. According to another exemplary embodiment of the present invention, the coil 130 may be disposed under the Hall effect device 120, as shown in FIG. 2B.

Meanwhile, the amplifier 140 amplifies the hall voltage outputted from the Hall effect device 120 at a predetermined magnitude. The amplified signal is outputted to the outside through a terminal OUT.

An operation principle of the integrated apparatus 100 for sensing current according to an exemplary embodiment of the present invention will be described with reference to FIGS. 1, 2A and 2B.

Referring to FIGS. 1, 2A and 2B, the current is supplied to the Hall effect device 120 by the voltage regulator 110. When the current i is inputted through the current input terminal I-IN of the integrated apparatus 100 for sensing current, the inputted current flows through the first connecting terminal P1, the coil 130, the second connecting terminal P2, and the current output terminal I-OUT. At this time, the magnetic field B is generated by the current i flowing to the coil 130, and the generated magnetic field B penetrates through the Hall effect device 120. The hall voltage is generated across the Hall effect device 120 by a Hall effect, and the generated hall voltage is transferred to the amplifier 141. The amplifier 141 amplifies the hall voltage and then outputs the amplified hall voltage to the outside through the terminal OUT.

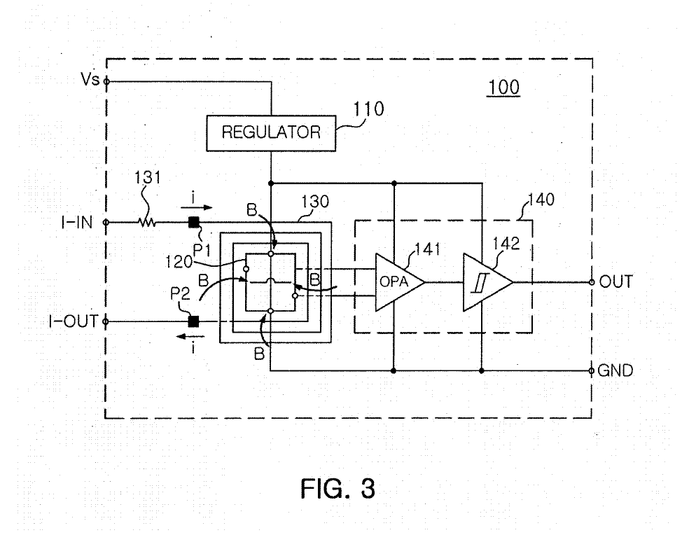

Meanwhile, FIG. 3 is a view showing an integrated apparatus for sensing current according to an exemplary embodiment of the present invention. The integrated apparatus for sensing current according to this exemplary embodiment of the present invention further includes a resistor 131 for limiting current and a Schmidt trigger 142, as compared to the integrated apparatus for sensing current shown in FIG. 1.

Generally, as the coil 130′ is integrated within one chip, when large current flows into the chip, significant heat may be generated in the coil 130 or the coil 130 may also be disconnected in a serious case. Accordingly, in order to prevent the above-mentioned problems, there is a need to limit the current flowing to the coil 130.

Referring to FIG. 3, the resistor 131 for limiting current may be connected between the current input terminal I-IN and the first connecting terminal P1. According to another exemplary embodiment of the present invention, the resistor 131 for limiting current may also be connected between the current output terminal I-OUT and the second connecting terminal P2. The resistor 131 for limiting current may also include a variable resistor.

In addition, a circuit converting the amplified voltage into a digital signal may be further provided behind the amplifier 141. Accordingly, a signal processing module 140 including the Schmidt trigger 142 behind the amplifier 141 is shown in FIG. 3.

More specifically, the amplifier 141 amplifies the hall voltage outputted from the Hall effect device 120 at the predetermined magnitude, and the Schmidt trigger 140 may convert the amplified voltage into the digital signal. The converted digital signal is outputted to the outside through a terminal OUT. The above-mentioned configuration of the signal processing module 140 is only an example, and the signal processing module may include an analog to digital converter (ADC) behind the amplifier 141, instead of the Schmidt trigger 140.

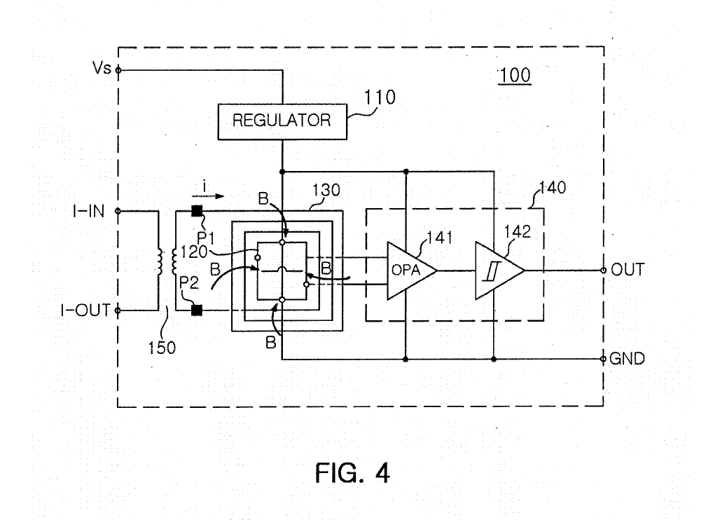

Meanwhile, the resistor 131 for limiting current may be replaced with a transformer 150, as shown in FIG. 4.

Referring to FIG. 4, the transformer 150 has a turn ratio of N:1, and has a primary side connected to the current input terminal I-IN and the current output terminal I-OUT and a secondary side connected to the first connecting terminal P1 and the second connecting terminal P2. The current flowing to the coil 130 connected to the first connecting terminal P1 and the second connecting terminal P2 of the secondary side may be appropriately controlled by adjusting the turn ratio of the transformer 150.

Meanwhile, although FIGS. 1, 3 and 4 of the present invention show particular components, the exemplary embodiments of the present invention is not limited thereto but may include various combinations of the components disclosed therein. More specifically, the resistor 131 for limiting current shown in FIG. 3 and the transformer 140 shown in FIG. 4 may be added to FIG. 1, and the Schmidt trigger 142 may also be removed from FIGS. 3 and 4 to output an analog type signal through the terminal OUT.

In addition, the above-mentioned components 110, 120, 130, 131, and 140 may be integrated within one chip. Alternatively, at least the Hall effect device 120 and the coil 130 may be integrated within one chip. A manufacturing cost of a product may be reduced, simultaneously with sensing the current without loss of the magnetic field according to a distance through the above-mentioned integration.

As set forth above, according to exemplary embodiments of the present invention, the Hall effect device outputting the hall voltage in proportion to the strength of the magnetic field and the coil generating the magnetic field are integrated within one chip, whereby a manufacturing cost of a product may be reduced, simultaneously with sensing current without loss of a magnetic field according to a distance.

While the present invention has been shown and described in connection with the exemplary embodiments, it will be apparent to those skilled in the art that modifications and variations can be made without departing from the spirit and scope of the invention as defined by the appended claims.

What is claimed is:

1. An integrated apparatus for sensing current, the integrated apparatus comprising:
a voltage regulator;
a Hall effect device receiving current by the voltage regulator and outputting hall voltage in proportion to a strength of a magnetic field; and
a coil having one end connected to a first connecting terminal and the other end connected to a second connecting terminal, wound to have a plurality of turns along a circumference of the Hall effect device on the same plane therewith, spaced apart by a predetermined distance from the Hall effect device in a direction of the magnetic field, and forming the magnetic field according to current flowing through the first connecting terminal and the second connecting terminal,
wherein the Hall effect device and the coil are integrated within one chip.

2. The integrated apparatus of claim 1, wherein the coil is disposed over or under the Hall effect device.

3. The integrated apparatus of claim 2, further comprising a resistor for limiting current between the first connecting terminal and a current input terminal or between the second connecting terminal and a current output terminal.

4. The integrated apparatus of claim 2, further comprising a transformer having a primary side connected to a current input terminal and a current output terminal and a secondary side connected to the first connecting terminal and the second connecting terminal.

5. The integrated apparatus of claim 1, further comprising an amplifier amplifying the hall voltage outputted from the Hall effect device.

6. The integrated apparatus of claim 5, further comprising a Schmidt trigger or an analog-to-digital converter converting the amplified voltage into a digital signal.
